(19) United States
(12) Patent Application Publication
(10) Pub. No.: US 2019/0260338 A1
(43) Pub. Date: Aug. 22, 2019

(54) POWER SUPPLY CONTROL DEVICE

(71) Applicants: AutoNetworks Technologies, Ltd., Yokkaichi (JP); Sumitomo Wiring Systems, Ltd., Yokkaichi (JP); Sumitomo Electric Industries, Ltd., Osaka (JP)

(72) Inventors: Kota Oda, Yokkaichi (JP); Masayuki Kato, Yokkaichi (JP); Shunichi Sawano, Yokkaichi (JP); Shinnosuke Nakaguchi, Yokkaichi (JP)

(21) Appl. No.: 16/277,373

(22) Filed: Feb. 15, 2019

(30) Foreign Application Priority Data
Feb. 21, 2018 (JP) 2018-029112

(51) Int. Cl. H03F 3/45; G05F 1/573; H02H 9/02; H02J 7/00; H03K 17/082

(52) U.S. Cl. CPC H03F 3/45076; G05F 1/573; H02H 9/025; H03F 2200/507; H02J 7/0063; H03K 17/0822; H02J 2007/0039; H02J 7/0029

(57) ABSTRACT

A power supply control device controls power supply via a switch by causing a drive circuit to turn on and off the switch. A first resistance is disposed on a path of a current flowing via the switch. A differential amplifier outputs a voltage corresponding to a value of a voltage between two ends of the first resistance. A first capacitor is connected between a point midway on a path of power supply to the differential amplifier and an upstream end of the first resistance. A second capacitor is connected between a point midway on the path of power supply and a downstream end of the first resistance.

### CROSS-REFERENCE TO RELATED APPLICATIONS

This application claims priority of Japanese Patent Application No. JP2018-029112 filed Feb. 21, 2018 the contents of which are incorporated herein.

### TECHNICAL FIELD

The present disclosure relates to a power supply control device.

### BACKGROUND

A vehicle may be equipped with a power supply control device that controls power supply via a switch by turning on and off the switch connected between a battery and a load (for example, see JP 2017-118791A). The power supply control device disclosed in JP 2017-118791A detects a value of a current flowing via the switch. When the detected current value is larger than or equal to a predetermined voltage value, the switch is turned off. This prevents an overcurrent from flowing via the switch.

### SUMMARY

One way of detecting a current value is to detect a voltage value between two ends of a resistance disposed on a path of current flowing via a switch. The larger the value of the current flowing via the switch is, the higher the voltage value between the two ends of the resistance is. Accordingly, the voltage value between the two ends of the resistance indicates the value of current flowing via the switch.

Moreover, the voltage value between the two ends of the resistance can be detected using a differential amplifier. In this case, one end of the resistance is connected to a first input terminal of the differential amplifier, and the other end of the resistance is connected to a second input terminal of the differential amplifier. The differential amplifier outputs a voltage corresponding to a voltage value between the first input terminal and the second input terminal, that is, the voltage value between the two ends of the resistance. The higher the voltage value between the two ends of the resistance is, or more specifically, the larger the value of current flowing via the switch is, the higher or the lower the value of the voltage outputted from the differential amplifier is.

The differential amplifier includes a power supply terminal that is supplied with power. The power supply terminal is connected to a positive terminal of a battery. The differential amplifier is supplied with power from the battery via the power supply terminal.

Disturbance noise containing an alternating-current component may be present in a conducting wire connecting the battery and the switch. In this case, the disturbance noise is inputted to the power supply terminal, the first input terminal, and the second input terminal of the differential amplifier. Here, propagation paths of the disturbance noise inputted to the power supply terminal, the first input terminal, and the second input terminal are different. For this reason, waveforms of the disturbance noise inputted to the power supply terminal, the first input terminal, and the second input terminal are different. Moreover, timings at which the disturbance noise is inputted to the power supply terminal, the first input terminal, and the second input terminal are also different.

Thus, when the disturbance noise is present in the differential amplifier, at least one of the voltage value of the power supply terminal with respect to the potential of the first input terminal and the voltage value of the power supply terminal with respect to the potential of the second input terminal fluctuates. When at least one of the voltage value of the power supply terminal with respect to the potential of the first input terminal and the voltage value of the power supply terminal with respect to the potential of the second input terminal fluctuates, the value of the voltage outputted from the differential amplifier fluctuates regardless of the value of the current flowing via the switch. As a result, an erroneous voltage is outputted from the differential amplifier.

The present disclosure is conceived in view of the circumstances described above, and it is an object of the present disclosure to provide a power supply control device including a differential amplifier that outputs an appropriate voltage.

A power supply control device according to an aspect of the present embodiment controls power supply via a switch by turning the switch on and off. The power supply control device includes: a resistance disposed on a path of a current flowing via the switch; a differential amplifier outputting a voltage corresponding to a value of a voltage between two ends of the resistance; a first capacitor connected between a point midway on a path of power supply to the differential amplifier and an upstream end of the resistance; and a second capacitor connected between a point midway on the path of power supply and a downstream end of the resistance.

According to the above aspect, an appropriate voltage is outputted from the differential amplifier.

### BRIEF DESCRIPTION OF THE DRAWINGS

FIG. 1 is a block diagram showing a configuration of main components included in a power system according to Embodiment 1;

FIG. 2 is a flowchart showing a procedure of power supply control processing;

FIG. 3 is a circuit diagram of a current detection circuit;

FIG. 4 is a diagram showing waveforms of a power supply voltage value, a first input voltage value, and a difference value when a first capacitor is not provided;

FIG. 5 is a diagram showing waveforms of the power supply voltage value, the first input voltage value, and the difference value when the first capacitor is provided;

FIG. 6 is a diagram showing waveforms of the first input voltage value, a second input voltage value, and a difference value when a third capacitor is not provided;

FIG. 7 is a diagram showing waveforms of the first input voltage, the second input voltage value, and the difference value when the third capacitor is provided;

FIG. 8 is a circuit diagram of a current detection circuit according to Embodiment 2;

FIG. 9 is a circuit diagram of a current detection circuit according to Embodiment 3; and

FIG. 10 is a circuit diagram of a current detection circuit according to Embodiment 4.

### DETAILED DESCRIPTION OF PREFERRED EMBODIMENTS OF THE

First, aspects of the present disclosure are described in detail. The embodiments described below may be freely combined at least partially.

A power supply control device according to an aspect of the present disclosure controls power supply via a switch by turning the switch on and off. The power supply control device includes: a resistance disposed on a path of a current flowing via the switch; a differential amplifier outputting a voltage corresponding to a value of a voltage between two ends of the resistance; a first capacitor connected between a point midway on a path of power supply to the differential amplifier and an upstream end of the resistance; and a second capacitor connected between a point midway on the path of power supply and a downstream end of the resistance.

According to the aspect described above, an alternating-current component of the voltage moves bidirectionally in the differential amplifier, via the first capacitor, between a power supply terminal supplied with power and a first input terminal receiving the voltage from the upstream end of the first resistance. As a result, the voltage values of the power supply terminal and the first input terminal fluctuate in the same manner during the presence of the disturbance noise in the power supply terminal or the first input terminal. Thus, the difference in voltage value between the power supply terminal and the first input terminal hardly fluctuates. Moreover, an alternating-current component of the voltage moves bidirectionally in the differential amplifier, via the second capacitor, between the power supply terminal and a second input terminal receiving the voltage from the downstream end of the first resistance. As a result, the voltage values of the power supply terminal and the second input terminal fluctuate in the same manner during the presence of the disturbance noise in the power supply terminal or the second input terminal. Thus, the difference in voltage value between the power supply terminal and the second input terminal hardly fluctuates.

From the above, both the difference in voltage value between the power supply terminal and the first input terminal and the difference in voltage value between the power supply terminal and the second input terminal are substantially constant even if disturbance noise is present. This allows the differential amplifier to output an appropriate voltage.

A power supply control device according to another aspect of the present disclosure includes: a variable resistor having a first end connected to the upstream end of the resistance, and fluctuating in a resistance value between the first end and a second end depending on a value of the voltage outputted from the differential amplifier; and a second resistance having one end connected to the second end of the variable resistor. The voltage is outputted from a connection node between the variable resistor and the second resistance.

According to the aspect described above, the voltage divided between the variable resistor and the second resistance is outputted. The value of this voltage indicates the value of the current flowing via the resistance.

A power supply control device according to another aspect of the present disclosure includes the variable resistor that is a transistor. The resistance value between the first end and the second end depends on a value of a voltage inputted to a control end of the variable resistor. The differential amplifier outputs a voltage to the control end.

According to the aspect described above, the transistor is used as the variable resistor. This achieves a simple configuration of the power supply control device.

In a power supply control device according to another aspect of the present disclosure, an end of the first capacitor on the supply-path side is connected to an end of the second capacitor on the supply-path side.

According to the aspect described above, one end of the first capacitor is connected to one end of the second capacitor. Accordingly, the alternating-current component of the voltage does not move between the power supply terminal and the first input terminal of the differential amplifier via the second capacitor. Furthermore, the alternating-current component of the voltage does not move between the power supply terminal and the second input terminal of the differential amplifier via the first capacitor.

A power supply control device according to another aspect of the present disclosure includes a third resistance and a fourth resistance. The first capacitor is connected to the upstream end of the resistance via the third resistance. The second capacitor is connected to the downstream end of the resistance via the fourth resistance.

According to the aspect described above, the third resistance and the first capacitor form an RC filter. The fourth resistance and the second capacitor form another RC filter. When the other end of the first capacitor and the other end of the second capacitor are grounded, each of the voltage values of the first input terminal and the second input terminal with respect to the ground potential stabilizes. When the other end of the first capacitor and the other end of the second capacitor are not grounded, the difference in voltage value between the power supply terminal and the first input terminal and the difference in voltage value between the power supply terminal and the second input terminal stabilize more.

In a power supply control device according to another aspect of the present disclosure, the first capacitor is connected at the point midway on the path of power supply via the second capacitor.

According to the aspect described above, the first capacitor is connected midway on the path of power supply via the second capacitor. Thus, the alternating-current component of the voltage moves bidirectionally between the power supply terminal and the first input terminal via the first capacitor and the second capacitor.

In a power supply control device according to another aspect of the present disclosure, the second capacitor is connected at the point midway on the path of power supply via the first capacitor.

According to the aspect described above, the second capacitor is connected midway on the path of power supply via the first capacitor. Thus, the alternating-current component of the voltage moves bidirectionally between the power supply terminal and the second input terminal via the first capacitor and the second capacitor.

A power supply control device according to another aspect of the present disclosure includes a first inductor, a second inductor, and a third capacitor that is connected between the two ends of the resistance. The first capacitor is connected to the upstream end of the resistance via the first inductor. The second capacitor is connected to the downstream end of the resistance via the second inductor.

According to the aspect described above, the first or second capacitor, the third capacitor, the first inductor, and the second inductor form a pi-type LC filter. Thus, the difference in voltage value between the first input terminal and the second input terminal stabilizes

A power supply control device according to another aspect of the present disclosure includes a fourth capacitor connected between the two ends of the resistance.

According to the aspect described above, the alternating-current component of the voltage moves between the two ends of the first resistance via the fourth capacitor. As a result, the voltage values of the first input terminal and the second input terminal fluctuate in the same manner during the presence of the disturbance noise in the first input terminal or the second input terminal. Thus, the difference in voltage value between the first input terminal and the second input terminal hardly fluctuates. Hence, the difference in voltage value between the first input terminal and the second input terminal is substantially constant even if disturbance noise is present. This allows the differential amplifier to output a more appropriate voltage.

Specific examples of a power system according to embodiments of the present disclosure are described with reference to the drawings. It is intended that the scope of the present disclosure not be limited by these examples, but be defined by the claims set forth below. Meanings equivalent to the description of the claims and all modifications are intended for inclusion within the scope of the following claims.

### Embodiment 1

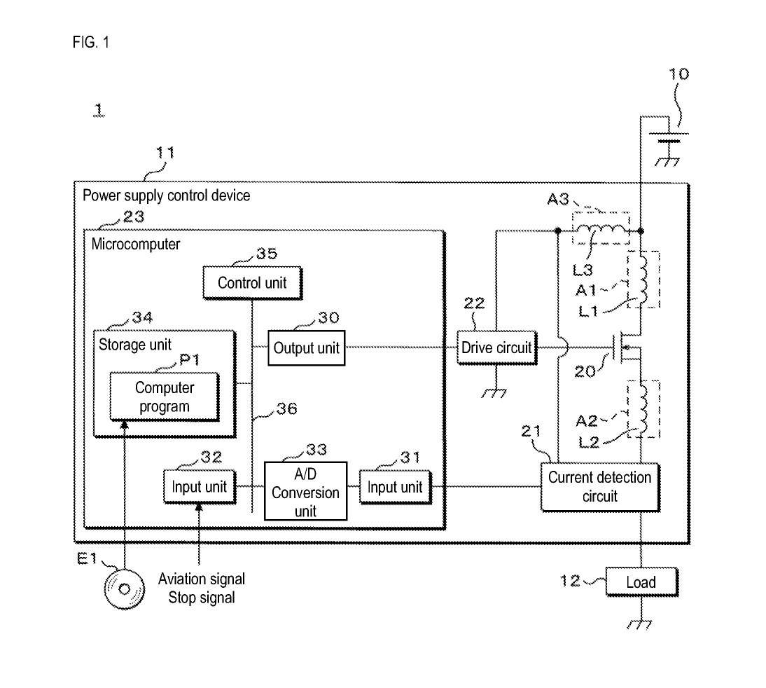

FIG. 1 is a block diagram showing a configuration of main components included in a power system 1 according to Embodiment 1. The power system 1 is suitably installed in a vehicle, and includes a battery 10, a power supply control device 11, and a load 12. A positive terminal of the battery 10 is connected to the power supply control device 11. The power supply control device 11 is further connected to one end of the load 12. A negative terminal of the battery 10 and the other end of the load 12 are grounded.

The battery 10 supplies power to the load 12 via the power supply control device 11. The load 12 is electrical equipment installed in the vehicle. When the battery 10 supplies power to the load 12, the load 12 starts operating. When power supply from the battery 10 to the load 12 stops, the load 12 stops operating.

The power supply control device 11 controls power supply from the battery 10 to the load 12. An activation signal for activating operation of the load 12 and a stop signal for stopping operation of the load 12 are inputted to the power supply control device 11. When the activation signal is inputted, the power supply control device 11 electrically connects the battery 10 to the load 12. With this, the battery 10 supplies power to the load 12, and the load 12 thus starts operating. When the stop signal is inputted, the power supply control device 11 electrically disconnects the battery 10 from the load 12. With this, power supply from the battery 10 to the load 12 stops, and the load 12 thus stops operating.

The power supply control device 11 includes a switch 20, a current detection circuit 21, a drive circuit 22, a microcomputer 23, and conducting wires A1, A2, and A3. The microcomputer 23 includes an output unit 30, input units 31 and 32, an A/D (Analog-to-Digital) conversion unit 33, a storage unit 34, and a control unit 35. The switch 20 is an N-channel FET (Field Effect Transistor).

A drain of the switch 20 is connected to the positive terminal of the battery 10 via the conducting wire A1. A source of the switch 20 is connected to the current detection circuit 21 via the conducting wire A2. The current detection circuit 21 is further connected to one end of the load 12. The current detection circuit 21 and the drive circuit 22 are connected to the positive terminal of the battery 10 via the conducting wire A3. The drive circuit 22 is further connected to a gate of the switch 20 and to the output unit 30 of the microcomputer 23. Moreover, the drive circuit 22 is grounded. The current detection circuit 21 is further connected to the input unit 31 of the microcomputer 23.

In the microcomputer 23, the input unit 31 is further connected to the A/D conversion unit 33. The output unit 30, the input unit 32, the A/D conversion unit 33, the storage unit 34, and the control 35 are connected to an internal bus 36. Each of the conducting wires A1, A2, and A3 is, for example, a conductive pattern formed on a circuit substrate. As shown in FIG. 1, equivalent circuits of the conducting wires A1, A2, and A3 are indicated as inductors L1, L2, and L3, respectively. Having the conducting wires A1, A2, and A3 corresponds to having the inductors L1, L2, and L3.

In the switch 20, when a voltage value of the gate with respect to the potential of the source is larger than or equal to a fixed voltage value, a current can flow via the drain and the source. In this case, the switch 20 is on. When the switch 20 is on, the battery 10 is electrically connected to the load 12 and supplies power to the load 12 via the switch 20 and the current detection circuit 21.

In the switch 20, when the voltage value of the gate with respect to the potential of the source is below the fixed voltage value, no current flows via the drain and the source. In this case, the switch 20 is off. When the switch 20 is off, the battery 10 is electrically disconnected from the load 12 and power supply from the battery 10 to the load 12 stops.

The current detection circuit 21 and the drive circuit 22 are supplied with power from the battery 10 via the conducting wire A3. The current detection circuit 21 and the drive circuit 22 operate using power supplied from the battery 10.

The output unit 30 outputs a high-level voltage or a low-level voltage to the drive circuit 22. In response to an instruction from the control unit 35, the output unit 30 switches the voltage outputted to the drive circuit 22 to the high-level voltage or the low-level voltage.

When the output unit 30 switches the voltage outputted to the drive circuit 22 from the low-level voltage to the high-level voltage, the drive circuit 22 increases the voltage value of the gate with respect to the ground potential. With this, in the switch 20, the voltage value of the gate with respect to the potential of the source increases to the fixed voltage value or higher. Thus, the switch 20 is turned on. As a result, the load 12 is supplied with power and starts operating.

When the output unit 30 switches the voltage outputted to the drive circuit 22 from the high-level voltage to the low-level voltage, the drive circuit 22 reduces the voltage value of the gate with respect to the ground potential. With this, in the switch 20, the voltage value of the gate with respect to the potential of the source decreases below the fixed voltage value. Thus, the switch 20 is turned off. As a result, power supply from the battery 10 to the load 12 stops, and the load 12 thus stops operating. As described thus far, with the drive circuit 22 that turns the switch 20 on and off, the power supply control device 11 controls power supply via the switch 20.

The current detection circuit 21 detects a value of a current flowing to the load 12 via the switch 20 (hereafter, this current value is referred to as the switch current value). The current detection circuit 21 outputs an analog switch voltage value indicating the detected switch current value to the input unit 31 of the microcomputer 23. When receiving the analog switch voltage value from the current detection circuit 21, the input unit 31 outputs the received analog switch voltage value to the A/D conversion unit 33. The A/D conversion unit 33 converts the analog switch voltage value into a digital switch voltage value. The control unit 35 obtains the digital switch voltage value from the A/D conversion unit 33. The switch current value indicated by the switch voltage value obtained by the control unit 35 is substantially equal to the switch current value when the switch voltage value is obtained.

The activation signal and the stop signal are inputted to the input unit 32. When the activation signal or the stop signal is inputted, the input unit 32 notifies the control unit 35 of the input signal.

The storage unit 34 is nonvolatile memory. The storage unit 34 stores a computer program P1. The control unit 35 has at least one CPU (Central Processing Unit). The at least one CPU of the control unit 35 executes the computer program P1 to perform power supply control processing by which power supply from the battery 10 to the load 12 via the switch 20 is controlled. The computer program P1 is used to cause the at least one CPU of the control unit 35 to perform the power supply control processing.

It should be noted that the computer program P1 may be stored in a storage medium E1 readable by the at least one CPU of the control unit 35. In this case, the computer program P1 read from the storage medium E1 by a read-out device (not shown) is stored into the storage unit 34. The storage medium E1 is an optical disk, a flexible disk, a magnetic disk, a magnetic optical disk, or semiconductor memory, for example. The optical disk is a CD-ROM (Compact Disc Read Only Memory), a DVD-ROM (Digital Versatile Disc Read Only Memory), or a BD (Blu-ray [registered trademark] Disc), for example. The magnetic disk is a hard disk, for example. Moreover, the computer program P1 may be downloaded from an external device (not shown) connected to a communication network (not shown). Then, the downloaded computer program P1 may be stored into the storage unit 34.

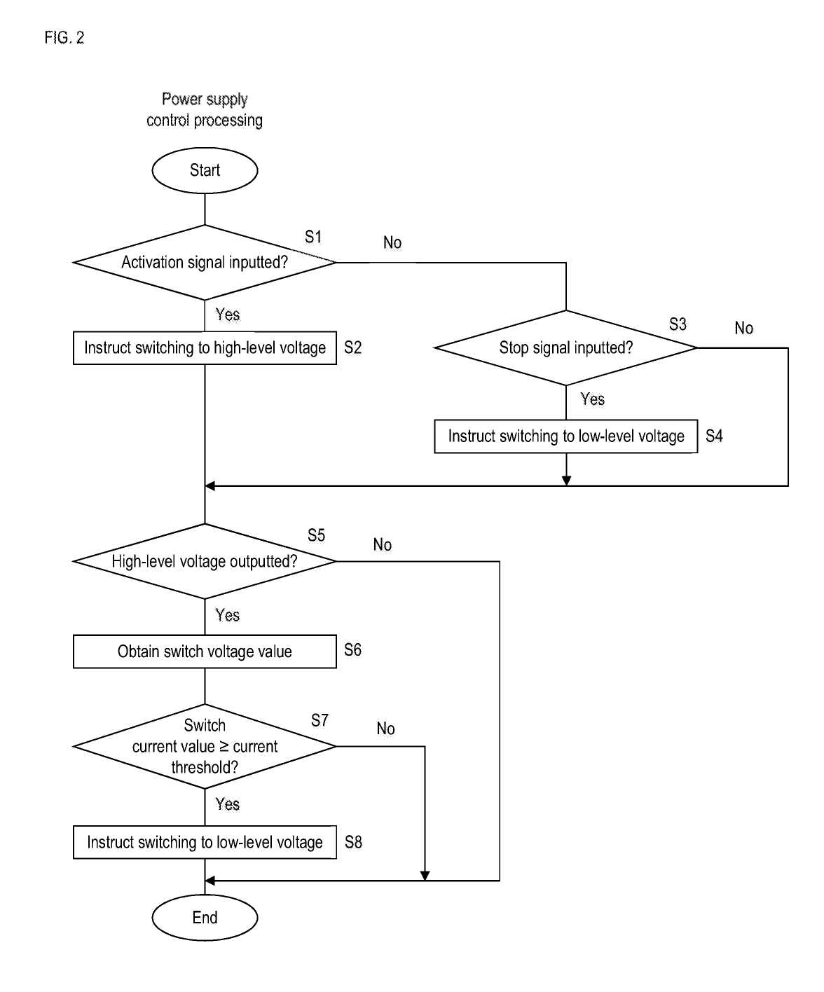

FIG. 2 is a flowchart showing a procedure of the power supply control processing. The control unit 35 periodically performs the power supply control processing. First, the control unit 35 determines whether the activation signal is inputted to the input unit 32 (Step S1). If determining that the activation signal is inputted (S1: YES), the control unit 35 instructs the output unit 30 to switch to the high-level voltage (Step S2). In response to this, the output unit 30 switches the voltage outputted to the drive circuit 22 to the high-level voltage. As a result, the drive circuit 22 turns on the switch 20. With this, the battery 10 supplies power to the load 12, and the load 12 thus starts operating.

If determining that the activation signal is not inputted (S1: NO), the control unit 35 determines whether the stop signal is inputted to the input unit 32 (Step S3). If determining that the stop signal is inputted (S3: YES), the control unit 35 instructs the output unit 30 to switch to the low-level voltage (Step S4). In response to this, the output unit 30 switches the voltage outputted to the drive circuit 22 to the low-level voltage. As a result, the drive circuit 22 turns off the switch 20. With this, power supply from the battery 10 to the load 12 stops, and the load 12 thus stops operating.

After executing one of Steps S2 and S4 or if determining that the stop signal is not inputted (S3: NO), the control unit 35 determines whether the output unit 30 outputs the high-level voltage (Step S5). As described above, when the output unit 30 outputs the high-level voltage, the switch 20 is on. When the output unit 30 outputs the low-level voltage, the switch 20 is off.

If determining that the output unit 30 outputs the high-level voltage (S5: YES), the control unit 35 obtains a digital switch voltage value from the A/D conversion unit 33 (Step S6). Then, the control unit 35 determines whether a switch current value indicated by the obtained switch voltage value is larger than or equal to a current threshold (Step S7). Here, the current threshold is a predetermined constant value.

If determining that the switch current value is larger than or equal to the current threshold (S7: YES), the control unit 35 instructs the output unit 30 to switch to the low-level voltage (Step S8). In response to this, the output unit 30 switches the voltage outputted to the drive circuit 22 to the low-level voltage and the drive circuit 22 turns off the switch 20. The control unit 35 ends the power supply control processing if determining that the output unit 30 is not outputting the high-level voltage (S5: NO), if determining that the switch current value is below the current threshold (S7: NO), or after executing Step S8.

As described thus far, in the power supply control device 11, when the activation signal is inputted to the input unit 32, the drive circuit 22 turns on the switch 20 to cause the load 12 to start operating. Moreover, when the stop signal is inputted to the input unit 32, the drive circuit 22 turns off the switch 20 to cause the load 12 to stop operating. Furthermore, when the switch current value is larger than or equal to the current threshold, the switch 20 is turned off so that overcurrent is prevented from flowing via the switch 20.

If ending the power supply control processing after executing Step S8, the control unit 35 does not execute the power supply control processing and the switch 20 is thus maintained off until a predetermined condition is satisfied. For example, the predetermined condition refers to the case where the stop signal and the activation signal are inputted in this order to the input unit 32 after the end of the power supply control processing.

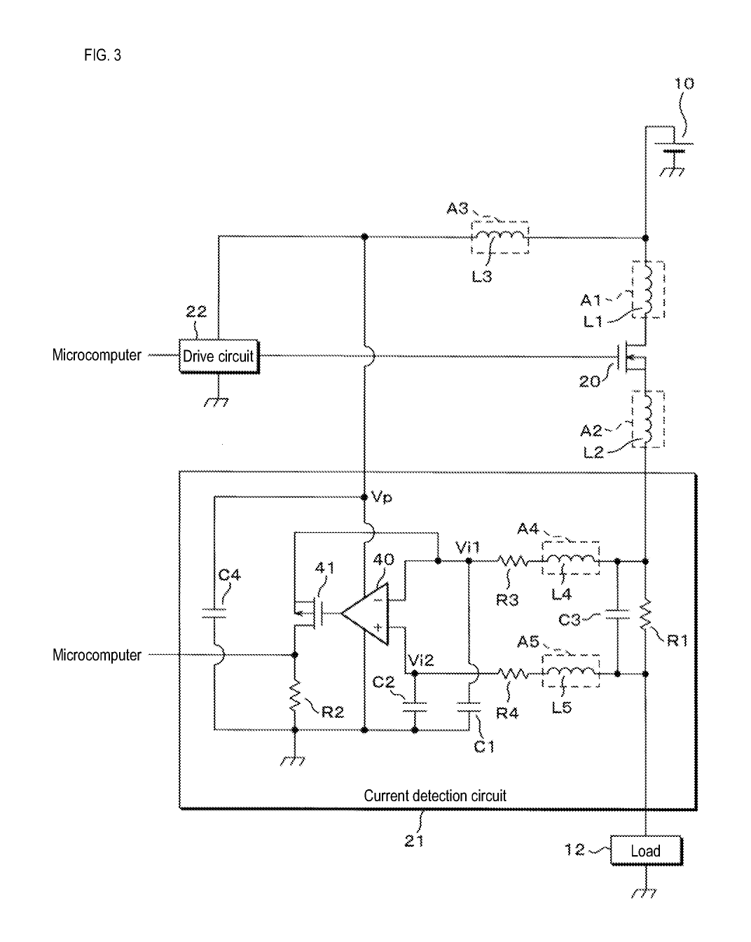

FIG. 3 is a circuit diagram of the current detection circuit 21. The current detection circuit 21 includes a differential amplifier 40, a transistor 41, a first capacitor C1, a second capacitor C2, a third capacitor C3, a bypass capacitor C4, a first resistance R1, a second resistance R2, a third resistance R3, a fourth resistance R4, and conducting wires A4 and A5. The differential amplifier 40 is a so-called operational amplifier, and has a power supply terminal, a GND terminal, a plus terminal, a minus terminal, and an output terminal. The transistor 41 is a P-channel FET.

One end of the first resistance R1 is connected to the source of the switch 20 via the conducting wire A2. The other end of the first resistance R1 is connected to one end of the load 12. When the switch 20 is on, the current flows from the positive terminal of the battery 10 to the conducting wire A1, to the switch 20, to the conducting wire A2, to the first resistance R1, and then to the load 12 in this order. Thus, the first resistance R1 is disposed on a path of the current flowing via the switch 20. The first resistance R1 is a so-called shunt resistance.

The third capacitor C3 is connected between two ends of the first resistance R1. The upstream end of the first resistance R1 is further connected to the minus terminal of the differential amplifier 40 via the conducting wire A4 and the third resistance R3. The downstream end of the first resistance R1 is further connected to the plus terminal of the differential amplifier 40 via the conducting wire A5 and the fourth resistance R4. The output terminal of the differential amplifier 40 is connected to a gate of the transistor 41. The third capacitor C3 also functions as a fourth capacitor.

The minus terminal of the differential amplifier 40 is further connected to a source of the transistor 41. Accordingly, the source of the transistor 41 is connected to the upstream end of the first resistance R1 via the third resistance R3 and the conducting wire A4. A drain of the transistor 41 is connected to one end of the second resistance R2. The other end of the second resistance R2 is grounded. A connection node between the drain of the transistor 41 and one end of the second resistance R2 is connected to the input unit 31 of the microcomputer 23. The minus terminal of the differential amplifier 40 is further connected to one end of the first capacitor C1. The plus terminal of the differential amplifier 40 is further connected to one end of the second capacitor C2. Accordingly, one end of the first capacitor C1 is connected to the upstream end of the first resistance R1 via the third resistance R3, and one end of the second capacitor C2 is connected to the downstream end of the first resistance R1 via the fourth resistance R4. The other end of the first capacitor C1 and the other end of the second capacitor C2 are also grounded.

The power supply terminal of the differential amplifier 40 is connected to the positive terminal of the battery 10 via the conducting wire A3. The GND terminal of the differential amplifier 40 is grounded. The power supply terminal of the differential amplifier 40 is further connected to one end of the bypass capacitor C4. The other end of the bypass capacitor C4 is grounded. Each of the conducting wires A4 and A5 is, for example, a conductive pattern formed on a circuit substrate, as with the conducting wires A1, A2, and A3. Equivalent circuits of the conducting wires A4 and A5 are indicated as inductors L4 and L5, respectively. Thus, one end of the first capacitor C1 is connected to the upstream end of the first resistance R1 via the inductor L4, and one end of the second capacitor C2 is connected to the downstream end of the first resistance R1 via the inductor L5. Having the conducting wires A4 and A5 corresponds to having the inductors L4 and L5. The inductor L4 functions as a first inductor, and the inductor L5 functions as a second inductor.

The battery 10 supplies power to the differential amplifier 40 via the conducting wire A3. In this case, the current is inputted to the power supply terminal of the differential amplifier 40 and outputted from the GND terminal of the differential amplifier 40. Thus, one end of the bypass capacitor C4 is connected at a point midway on a path of power supply to the differential amplifier 40.

The other end of the first capacitor C1 and the other end of the second capacitor C2 are connected midway on the path of power supply via the bypass capacitor 4. Thus, the first capacitor C1 is connected between a point midway on the path of power supply to the differential amplifier 40 and the upstream end of the first resistance R1. The second capacitor C2 is connected between a point midway on the path of power supply to the differential amplifier 40 and the downstream end of the first resistance R1. Since the other end of the first capacitor C1 and the other end of the second capacitor C2 are grounded, the path-side end of the first capacitor C1 is connected to the path-side end of the second capacitor C2.

The differential amplifier 40 outputs, to the gate of the transistor 41, a voltage corresponding to the voltage value between the two ends of the first resistance R1. For the differential amplifier 40, the higher the voltage value between the two ends of the first resistance R1 is, the lower the voltage value of the plus terminal with respect to the potential of the minus terminal is. When the voltage value between the two ends of the first resistance R1 is 0 V, the voltage value of the plus terminal with respect to the potential of the minus terminal is 0 V, which is the highest. The higher the voltage value of the plus terminal with respect to the potential of the minus terminal is, that is, the higher the voltage value between the two ends of the first resistance R1 is, the lower the voltage outputted from the differential amplifier 40 to the gate is.

The transistor 41 functions as a variable resistor. In the transistor 41, the lower the voltage value of the gate with respect to the potential of the source is, the lower the resistance value between the source and the drain is. The higher the voltage value of the gate with respect to the potential of the source is, the higher the resistance value between the source and the drain is. The source, the drain, and the gate of the transistor 41 function as a first end, a second end, and a control end, respectively.

The lower the value of the voltage outputted from the differential amplifier 40 to the gate of the transistor 41 is, that is, the higher the voltage value between the two ends of the first resistance R1 is, the lower the voltage value of the gate with respect to the potential of the source is and also the lower the resistance value between the source and the drain of the transistor 41 is.

The voltage value between the two ends of the first resistance R1 is expressed as a product of the value of the current flowing through the first resistance R1 and the resistance value of the first resistance R1. The resistance value of the third resistance R3 is sufficiently larger than the resistance value of the first resistance R1. For this reason, substantially all of the current flowing via the switch 20 flows to the first resistance R1. Thus, the value of the current flowing through the first resistance R1 is substantially equal to the value of the current flowing via the switch 20, that is, substantially equal to the switch current value.

Moreover, the resistance value of the first resistance R1 is constant. Accordingly, the larger the switch current value is, the higher the voltage value between the two ends of the first resistance R1 is. Thus, the larger the switch current value is, the lower the resistance value between the source and the drain of the transistor 41 is.

As with the resistance value of the third resistance R3, the resistance value of the fourth resistance R4 is also sufficiently larger than the resistance value of the first resistance R1. For this reason, nearly all of the current flowing via the first resistance R1, that is, nearly all of the current flowing via the switch 20 flows to the load 12.

When the switch 20 is on, the voltage outputted from the battery 10 is divided between the second resistance R2 and a combined resistance of the third resistance R3 and the transistor 41. The voltage divided between the second resistance R2 and the combined resistance of the third resistance R3 and the transistor 41 is outputted from the connection node between the transistor 41 and the second resistance R2 to the input unit 31 of the microcomputer 23. The value of the voltage divided between the second resistance R2 and the combined resistance of the third resistance R3 and the transistor 41 is inputted as an analog switch voltage value to the input unit 31. The combined resistance is expressed by the sum of the resistance value of the third resistance R3 and the resistance value between the source and the drain of the transistor 41.

When the switch current value is large, the voltage value between the two ends of the first resistance R1 is high and the resistance value between the source and the drain of the transistor 41 is small. Thus, the switch voltage value is high in this case. When the switch current value is small, the voltage value between the two ends of the first resistance R1 is low and the resistance value between the source and the drain of the transistor 41 is large. Thus, the switch voltage value is low in this case.

Note that the resistance values of the first resistance R1, the second resistance R2, and the third resistance R3 are represented by r1, r2, and r3, respectively. Note also that the value of current flowing through the first resistance R1 is represented by Ir. In this case, the switch voltage value Vs is expressed by the equation below to indicate the current value Ir. Here, the switch voltage value Vs is a voltage value with respect to the ground potential.

Vs=(Ir·r1·r2)/r3

As described above, nearly all of the current flowing via the switch 20 flows to the first resistance R1. Accordingly, the current value Ir can be substituted by the switch current value Is. Thus, the following equation is formulated.

Vs=(Is·r1·r2)/r3

Each of the resistance values r1, r2, and r3 is a constant value. Thus, the switch voltage value Vs is proportional to the switch current value Is and indicates the switch current value Is.

Hereinafter, the voltage value of the power supply terminal of the differential amplifier 40 with respect to the ground potential is referred to as the power supply voltage value. Moreover, the voltage values of the minus terminal and the plus terminal of the differential amplifier 40 with respect to the ground potential are referred to as the first input voltage value and the second input voltage value, respectively. Furthermore, the power supply voltage value, the first input voltage value, and the second input voltage value are indicated as Vp, Vi1, and Vi2, respectively.

The bypass capacitor C4 reduces fluctuations of the power supply voltage value Vp.

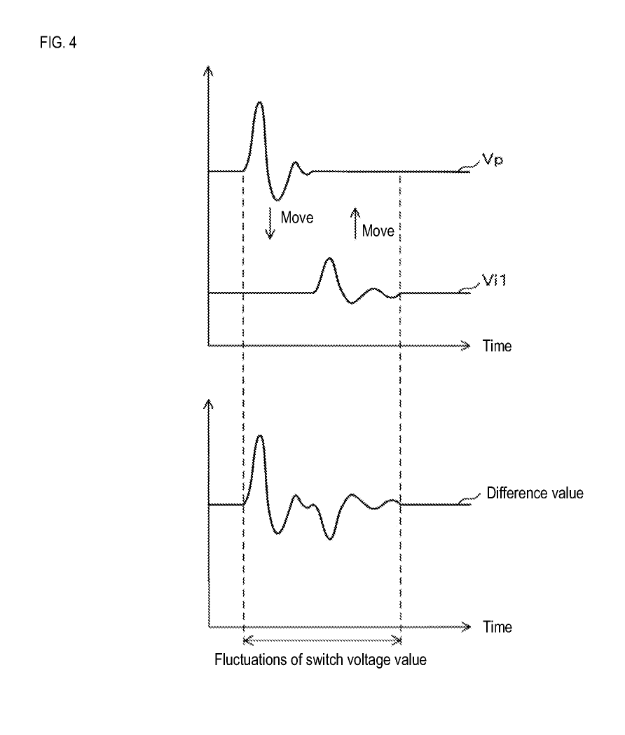

An operation of the first capacitor C1 is described. FIG. 4 is a diagram showing waveforms of the power supply voltage value Vp, the first input voltage value Vi1, and a difference value when the first capacitor C1 is not provided. The difference value shown in FIG. 4 is calculated by subtracting the first input voltage value Vi1 from the power supply voltage value Vp. The horizontal axis represents the time.

Disturbance noise containing an alternating-current component is present in the power system 1. Disturbance noise is an electromagnetic wave outputted from a mobile telephone, for example. This electromagnetic wave includes a frequency component in a 2 GHz band, for example. Suppose that disturbance noise is present in the conducting wire A3 when the switch 20 is on. In this case, a part of the disturbance noise is inputted to the power supply terminal of the differential amplifier 40. As a result, the voltage inputted to the power supply terminal of the differential amplifier 40 includes the alternating-current component, and the power supply voltage value Vp fluctuates as shown in FIG. 4.

Another part of the disturbance noise propagates to the conducting wire A1, to the switch 20, to the conducting wires A2 and A4, and to the third resistance R3 in this order, and then is inputted to the minus terminal of the differential amplifier 40. As a result, the voltage inputted to the minus terminal of the differential amplifier 40 includes the alternating-current component, and the first input voltage value Vi1 also fluctuates as shown in FIG. 4.

A propagation distance of the disturbance noise inputted to the power supply terminal of the differential amplifier 40 is different from a propagation distance of the disturbance noise inputted to the minus terminal of the differential amplifier 40. Accordingly, a timing at which the power supply voltage value Vp fluctuates due to the disturbance noise is different from a timing at which the first input voltage value Vil fluctuates due to the disturbance noise. Moreover, the impedance of the elements through which the disturbance noise inputted to the power supply terminal of the differential amplifier 40 passes is different from the impedance of the elements through which the disturbance noise inputted to the minus terminal of the differential amplifier 40 passes. For this reason, the waveform for the part subject to the disturbance noise inputted to the power supply terminal of the differential amplifier 40 is different from the waveform for the part subject to the disturbance noise inputted to the minus terminal of the differential amplifier 40.

As a result, the difference value between the power supply voltage value Vp and the first input voltage value Vi1 cannot be maintained constant and thus fluctuates due to the disturbance noise as shown in FIG. 4. Thus, when disturbance noise is present, the value of voltage outputted from the differential amplifier 40 fluctuates regardless of the switch current value Is and also the switch voltage value Vs fluctuates. Hence, the differential amplifier 40 outputs an erroneous voltage.

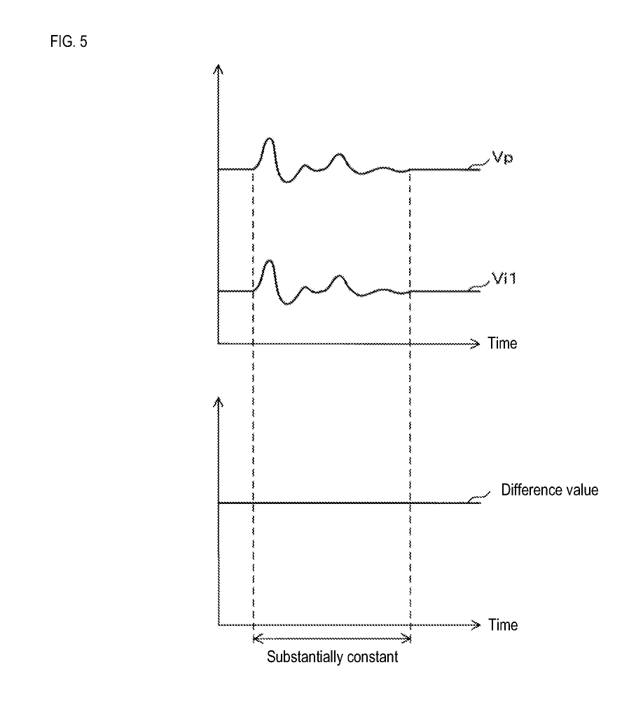

FIG. 5 is a diagram showing waveforms of the power supply voltage value Vp, the first input voltage value Vi1, and a difference value when the first capacitor C1 is provided. The difference value shown in FIG. 5 is also calculated by subtracting the first input voltage value Vi1 from the power supply voltage value Vp. The horizontal axis represents the time.

When the first capacitor C1 is provided, the alternating-current component of the voltage moves bidirectionally, as shown by the arrows in FIG. 4, between the power supply terminal and the minus terminal of the differential amplifier 40 via the first capacitor C1 and the bypass capacitor C4. As a result, the power supply voltage value Vp and the first input voltage value Vi1 fluctuate in the same manner during the presence of the disturbance noise in the power supply terminal or the minus terminal, as shown in FIG. 5. Thus, the difference value between the power supply voltage value Vp and the first input voltage value Vi1 hardly fluctuates. Moreover, the difference value is substantially constant.

Next, an operation of the second capacitor C2 is described. The second capacitor C2 operates in the same manner as the first capacitor C1. Suppose that disturbance noise is present in the conducting wire A3 when the switch 20 is on. In this case, a part of the disturbance noise is inputted to the power supply terminal of the differential amplifier 40. As a result, the voltage inputted to the power supply terminal of the differential amplifier 40 includes the alternating-current component, and the power supply voltage value Vp fluctuates. Another part of the disturbance noise propagates to the conducting wire A1, to the switch 20, to the conducting wire A2, to the first resistance R1, to the conducting wire A5, and to the fourth resistance R4 in this order, and then is inputted to the plus terminal of the differential amplifier 40. As a result, the voltage inputted to the plus terminal of the differential amplifier 40 includes the alternating-current component, and the second input voltage value Vi2 fluctuates as with the first input voltage value Vi1.

When the second capacitor C2 is not provided, a propagation path of the disturbance noise inputted to the power supply terminal of the differential amplifier 40 is different from a propagation path of the disturbance noise inputted to the plus terminal of the differential amplifier 40. Accordingly, a timing at which the power supply voltage value Vp fluctuates due to the disturbance noise is different from a timing at which the second input voltage value Vi2 fluctuates due to the disturbance noise. Moreover, the waveform for the part having the disturbance noise inputted to the power supply terminal of the differential amplifier 40 is different from the waveform for the part having the disturbance noise inputted the plus terminal of the differential amplifier 40. Thus, when disturbance noise is present, the value of voltage outputted from the differential amplifier 40 fluctuates regardless of the switch current value Is and also the switch voltage value Vs fluctuates. Hence, the differential amplifier 40 outputs an erroneous voltage.

When the second capacitor C2 is provided, the alternating-current component of the voltage moves bidirectionally between the power supply terminal and the plus terminal of the differential amplifier 40 via the second capacitor C2 and the bypass capacitor C4. As a result, the power supply voltage value Vp and the second input voltage value Vi2 fluctuate in the same manner during the presence of the disturbance noise in the power supply terminal or the plus terminal. Thus, the difference value between the power supply voltage value Vp and the second input voltage value Vi2 hardly fluctuates. Moreover, the difference value is substantially constant.

As described thus far, when the first capacitor C1 and the second capacitor C2 are provided, both the difference value between the power supply voltage Vp and the first input voltage value Vi1 and the difference value between the power supply voltage Vp and the second input voltage value Vi2 are substantially constant even if disturbance noise is present. This allows the differential amplifier 40 to output an appropriate voltage corresponding to the voltage between the two ends of the first resistance R1. Moreover, the switch voltage value Vs precisely indicates the voltage value between the two ends of the first resistance R1, that is, the switch current value Is.

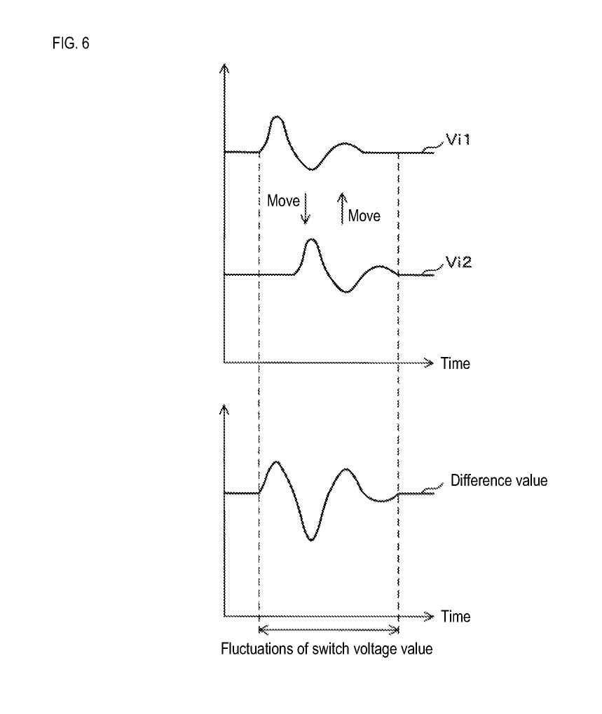

Next, an operation of the third capacitor C3 is described. FIG. 6 is a diagram showing waveforms of the first input voltage value Vi1, the second input voltage value Vi2, and a difference value when the third capacitor C3 is not provided. The difference value shown in FIG. 6 is calculated by subtracting the second input voltage value Vi2 from the first input voltage value Vi1. The horizontal axis represents the time.

Suppose that disturbance noise is present in the conducting wire A2 when the switch 20 is on. In this case, a part of the disturbance noise is inputted to the minus terminal of the differential amplifier 40 via the conducting wire A4 and the third resistance R3. As a result, the voltage inputted to the minus terminal of the differential amplifier 40 includes the alternating-current component, and the first input voltage value Vi1 fluctuates. Another part of the disturbance noise is inputted to the minus terminal of the differential amplifier 40 via the first resistance R1, the conducting wire A5, and the fourth resistance R4. As a result, the voltage inputted to the plus terminal of the differential amplifier 40 includes the alternating-current component, and the second input voltage value Vi2 also fluctuates.

A propagation distance of the disturbance noise inputted to the minus terminal of the differential amplifier 40 is different from a propagation distance of the disturbance noise inputted to the plus terminal of the differential amplifier 40. Accordingly, a timing at which the first input voltage value Vil fluctuates due to the disturbance noise is different from a timing at which the second input voltage value Vi2 fluctuates due to the disturbance noise. Moreover, impedance of an element through which the disturbance noise inputted to the minus terminal of the differential amplifier 40 passes is different from impedance of an element through which the disturbance noise inputted to the plus terminal of the differential amplifier 40 passes. For this reason, the waveform for the part having the disturbance noise inputted to the minus terminal of the differential amplifier 40 is different from the waveform for the part having the disturbance noise inputted the plus terminal of the differential amplifier 40.

As a result, the difference value between the first input voltage value Vi1 and the second input voltage value Vi2 fluctuates as shown in FIG. 6. Thus, when disturbance noise is present, the value of voltage outputted from the differential amplifier 40 fluctuates regardless of the switch current value Is and also the switch voltage value Vs fluctuates. Hence, the differential amplifier 40 outputs an erroneous voltage.

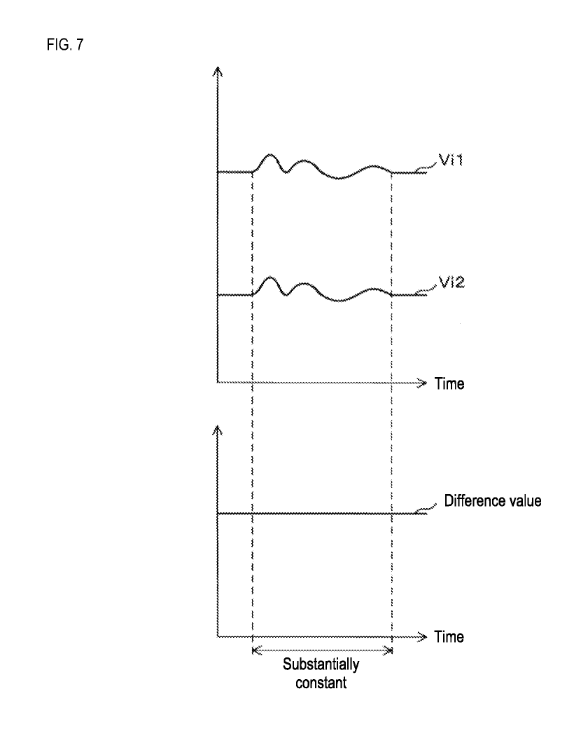

FIG. 7 is a diagram showing waveforms of the first input voltage value Vil, the second input voltage value Vi2, and a difference value when the third capacitor C3 is provided. The difference value shown in FIG. 7 is also calculated by subtracting the second input voltage value Vi2 from the first input voltage value Vil. The horizontal axis represents the time.

When the third capacitor C3 is provided, the alternating-current component of the voltage moves bidirectionally, as shown by the arrows in FIG. 6, between the two ends of the first resistance R1 via the third capacitor C3. As a result, the first input voltage value Vi1 and the second input voltage value Vi2 fluctuate in the same manner during the presence of the disturbance noise in the plus terminal or the minus terminal, as shown in FIG. 7. Thus, the difference value between the first input voltage value Vil and the second input voltage value Vi2 hardly fluctuates. Moreover, the difference value is substantially constant.

Thus, when the third capacitor C3 is provided, the difference value between the first input voltage value Vil and the second input voltage value Vi2 is substantially constant even if disturbance noise is present. This allows the differential amplifier 40 to output an appropriate voltage corresponding to the voltage between the two ends of the first resistance R1. Moreover, the switch voltage value Vs precisely indicates the voltage value between the two ends of the first resistance R1, that is, the switch current value Is.

The power supply control device 11 includes the transistor 41 as the variable resistor. This achieves a simple configuration of the power supply control device 11. Moreover, the other end of the first capacitor C1 is connected to the other end of the second capacitor C2. Accordingly, the alternating-current component of the voltage does not move between the power supply terminal and the first input terminal of the differential amplifier 40 via the second capacitor C2. Furthermore, the alternating-current component of the voltage does not move between the power supply terminal and the second input terminal of the differential amplifier 40 via the first capacitor C1.

Moreover, the third resistance R3 and the first capacitor C1 form an RC filter. The fourth resistance R4 and the second capacitor C2 form another RC filter. The other end of the first capacitor C1 and the other end of the second capacitor C2 are grounded. Thus, each of the first input voltage value Vi1 and the second input voltage value Vi2 with respect to the ground potential stabilizes.

### Embodiment 2

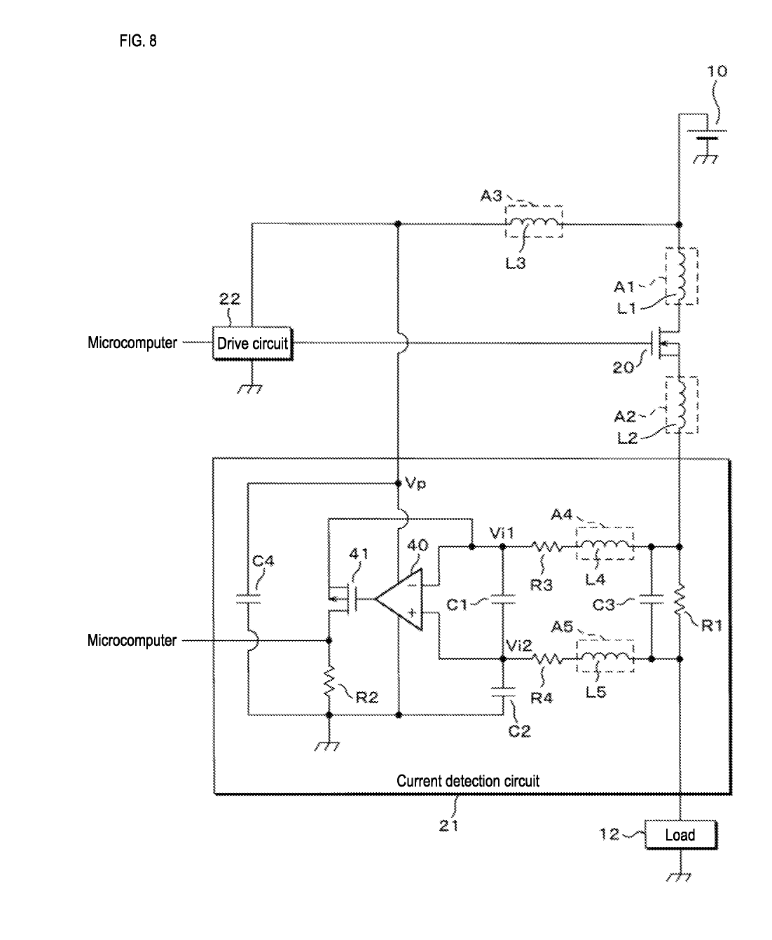

FIG. 8 is a circuit diagram of a current detection circuit 21 according to Embodiment 2. In the following, Embodiment 2 is described based on differences between Embodiment 1 and Embodiment 2. The configuration according to Embodiment 2 is identical to the configuration according to Embodiment 1, except for the part described below. Thus, the components identical to those in Embodiment 1 are assigned the same reference numerals used in Embodiment 1 and the description of these components is omitted.

Embodiment 2 is different from Embodiment 1 in the connection of a first capacitor C1 of the current detection circuit 21 in a power supply control device 11. As in Embodiment 1, one end of the first capacitor C1 is connected to an upstream end of a first resistance R1 via a third resistance R3 and a conducting wire A4, according to Embodiment 2. The other end of the first capacitor C1 is connected to one end of a second capacitor C2. As described in Embodiment 1, one end of a bypass capacitor C4 is connected at a point midway on a path of power supply to a differential amplifier 40. The other end of the second capacitor C2 and the other end of the bypass capacitor C4 are grounded. Thus, the other end of the first capacitor C1 is connected at a point midway on the path of power supply via the second capacitor C2 and the bypass capacitor C4.

In the power supply control device 11 having the above configuration according to Embodiment 2, an alternating-current component of the voltage moves bidirectionally between a power supply terminal and a minus terminal of the differential amplifier 40 via the first capacitor C1, the second capacitor C2, and the bypass capacitor C4. As a result, a power supply voltage value Vp and a first input voltage value Vi1 fluctuate in the same manner during the presence of disturbance noise, as in Embodiment 1. Thus, the difference value between the power supply voltage value Vp and the first input voltage value Vi1 hardly fluctuates.

Moreover, the first capacitor C1, a third capacitor C3, and inductors L4 and L5 form a pi-type LC filter. Thus, the difference value between the first input voltage value Vi1 and a second input voltage value Vi2 stabilizes more.

The power supply control device 11 according to Embodiment 2 achieves the same effects as the power supply control device 11 according to Embodiment 1, except for the following effects. The excluded effects include: the effect obtained by the connection between the path-side end of the first capacitor C1 and the path-side end of the second capacitor C2; the effect obtained by the RC filter formed by the third resistance R3 and the first capacitor C1; and the effect obtained by the additional RC filter formed by the fourth resistance R4 and the second capacitor C2. It should be noted that each of the inductors L4 and L5 according to Embodiment 2 is not limited to an inductor component contained in the corresponding one of the conducting wires A4 and A5, and may be an element.

### Embodiment 3

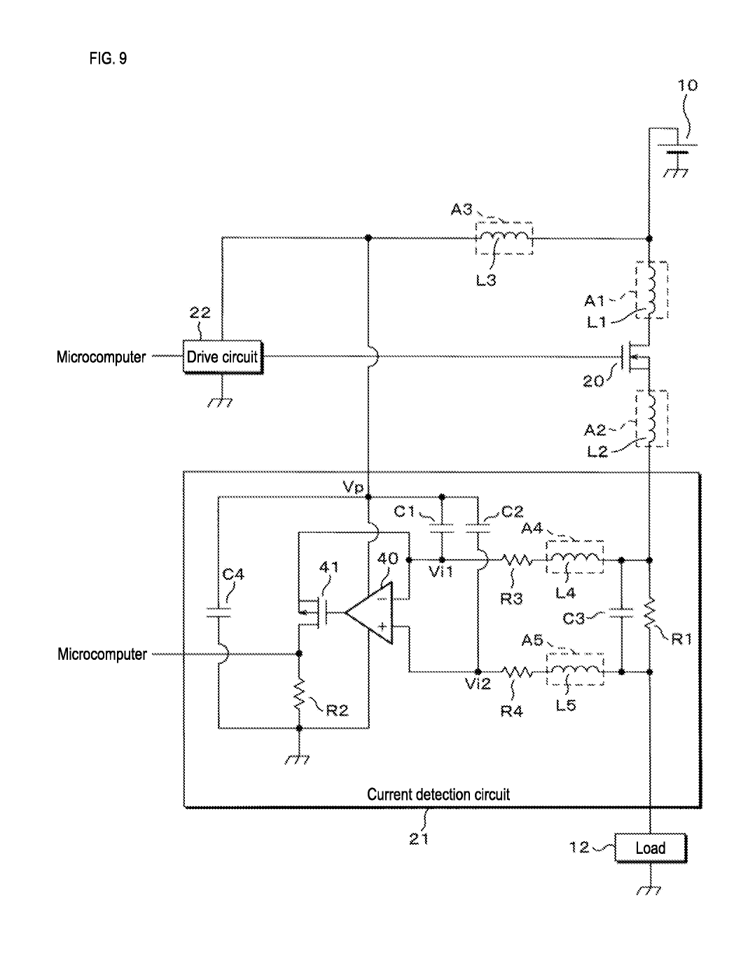

FIG. 9 is a circuit diagram of a current detection circuit 21 according to Embodiment 3. In the following, Embodiment 3 is described based on differences between Embodiment 1 and Embodiment 3. The configuration according to Embodiment 3 is identical to the configuration according to Embodiment 1, except for the part described below. Thus, the components identical to those in Embodiment 1 are assigned the same reference numerals used in Embodiment 1 and the description of these components is omitted.

Embodiment 3 is different from Embodiment 1 in the connections of a first capacitor C1 and a second capacitor C2 of the current detection circuit 21 in a power supply control device 11. As in Embodiment 1, one end of the first capacitor C1 is connected to an upstream end of a first resistance R1 via a third resistance R3 and a conducting wire A4, and one end of the second capacitor C2 is connected to a downstream end of the first resistance R1 via a fourth resistance R4 and a conducting wire A5, according to Embodiment 3. The other end of the first capacitor C1 and the other end of the second capacitor C2 are connected to a power supply terminal of a differential amplifier 40 without involving a bypass capacitor C4. The other end of the first capacitor C1 and the other end of the second capacitor C2 are not grounded.

As described in Embodiment 1 above, a battery 10 supplies power to the differential amplifier 40 via a conducting wire A3. Here, the current is inputted to the power supply terminal of the differential amplifier 40 and outputted from a GND terminal of the differential amplifier 40. Thus, the other end of the first capacitor C1 and the other end of the second capacitor C2 are connected midway on a path of power supply to the differential amplifier 40. The path-side end of the first capacitor C1 is connected to the path-side end of the second capacitor C2.

In the power supply control device 11 having the above configuration according to Embodiment 3, an alternating-current component of the voltage moves bidirectionally between the power supply terminal and a minus terminal of the differential amplifier 40 via the first capacitor C1. Moreover, an alternating-current component of the voltage moves bidirectionally between the power supply terminal and a plus terminal of the differential amplifier 40 via the second capacitor C2.

Furthermore, as in Embodiment 1, an RC filter is formed by the third resistance R3 and the first capacitor C1, and another RC filter is formed by the fourth resistance R4 and the second capacitor C2. Moreover, the other end of the first capacitor C1 and the other end of the second capacitor C2 are connected midway on the path of power supply to the differential amplifier 40, instead of being grounded. Thus, a difference value between a power supply voltage value Vp and a first input voltage value Vil and a difference value between the power supply voltage value Vp and a second input voltage value Vi2 stabilize more.

The power supply control device 11 according to Embodiment 3 achieves the same effects as the power supply control device 11 according to Embodiment 1, except for the following effects. The excluded effects include: the effect obtained by the RC filter formed by the third resistance R3 and the first capacitor C1; and the effect obtained by the additional RC filter formed by the fourth resistance R4 and the second capacitor C2.

### Embodiment 4

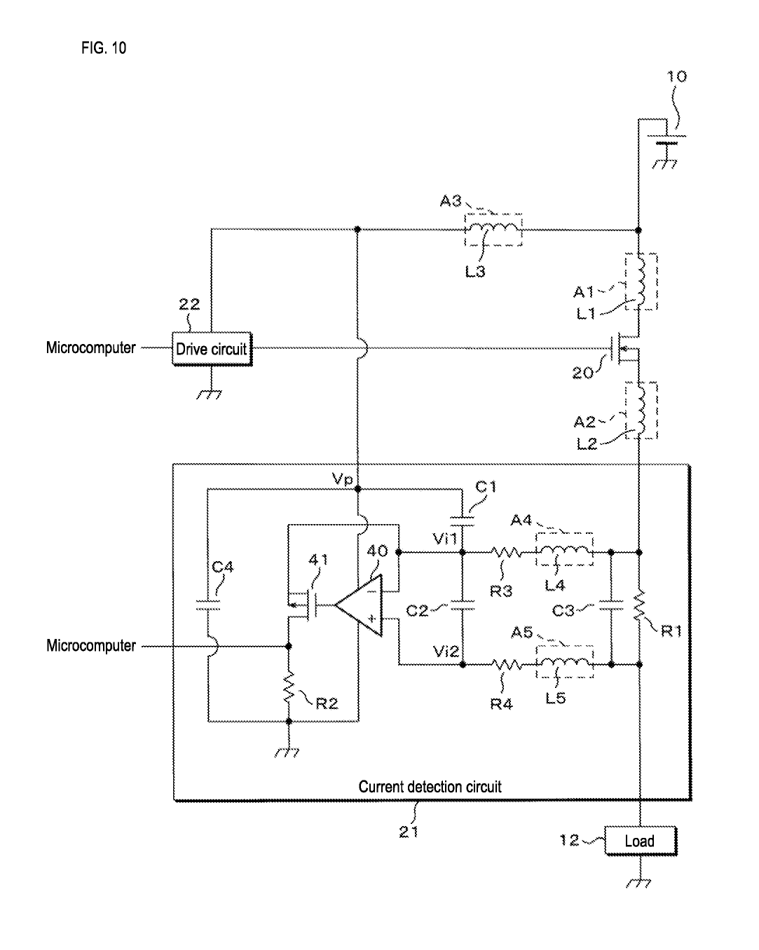

FIG. 10 is a circuit diagram of a current detection circuit 21 according to Embodiment 4. In the following, Embodiment 4 is described based on differences between Embodiment 3 and Embodiment 4. The configuration according to Embodiment 4 is identical to the configuration according to Embodiment 3, except for the part described below. Thus, the components identical to those in Embodiment 3 are assigned the same reference numerals used in Embodiment 3 and the description of these components is omitted.

Embodiment 4 is different from Embodiment 3 in the connection of a second capacitor C2 of the current detection circuit 21 in a power supply control device 11. As in Embodiment 3, one end of the second capacitor C2 is connected to a downstream end of a first resistance R1 via a fourth resistance R4 and a conducting wire A5 according to Embodiment 4. The other end of the second capacitor C2 is connected to one end of a first capacitor C1. As described in Embodiment 3, the other end of the first capacitor C1 is connected at a point midway on a path of power supply to a differential amplifier 40. Thus, the other end of the second capacitor C2 is connected at a point midway on the path of power supply via the first capacitor C1.

In the power supply control device 11 having the above configuration according to Embodiment 4, an alternating-current component of the voltage moves bidirectionally between a power supply terminal and a plus terminal of the differential amplifier 40 via the first capacitor C1 and the second capacitor C2. As a result, a power supply voltage value Vp and a second input voltage value Vi2 fluctuate in the same manner during the presence of disturbance noise, as in Embodiment 3. Thus, the difference value between the power supply voltage value Vp and the second input voltage value Vi2 hardly fluctuates.

Moreover, the second capacitor C2, a third capacitor C3, and inductors L4 and L5 form a pi-type LC filter. Thus, the difference value between the first input voltage value Vil and the second input voltage value Vi2 stabilizes more.

The power supply control device 11 according to Embodiment 4 achieves the same effects as the power supply control device 11 according to Embodiment 3, except for the following effects. The excluded effects include: the effect obtained by the connection of the other end of the second capacitor C2 midway on the path of power supply without involving the first capacitor C1; the effect obtained by the RC filter formed by the third resistance R3 and the first capacitor C1; and the effect obtained by the additional RC filter formed by the fourth resistance R4 and the second capacitor C2. It should be noted that, as in Embodiment 2, each of the inductors L4 and L5 according to Embodiment 4 is not limited to an inductor component contained in the corresponding one of the conducting wires A4 and A5, and may be an element.

It should be noted that the transistor 41 according to Embodiments 1 to 4 is not limited to the P-channel FET, and may be a PNP bipolar transistor. In this case, an emitter, a collector, and a base of the PNP bipolar transistor correspond to the source, the drain, and the gate of the P-channel FET, respectively.

Moreover, the transistor 41 may be an N-channel FET. In this case, the plus terminal of the differential amplifier 40 is connected to the upstream end of the first resistance R1 via the third resistance R3 and the conducting wire A4. Also in this case, the minus terminal of the differential amplifier 40 is connected to the downstream end of the first resistance R1 via the fourth resistance R4 and the conducting wire A5. The higher the voltage value between the two ends of the first resistance R1 is, the higher the value of the voltage outputted from the differential amplifier 40 is. The drain of the transistor 41 is connected to the plus terminal of the differential amplifier 40, and the source of the transistor 41 is connected to one end of the second resistance R2.

The higher the voltage value of the gate with respect to the potential of the source is, that is, the higher the value of the voltage outputted from the differential amplifier 40 is, the smaller the resistance value between the drain and the source of the transistor 41 is. The voltage is outputted from the connection node between the transistor 41 and the second resistance R2 to the input unit 31 of the microcomputer 23. The smaller the resistance value between the drain and the source of the transistor 41 is, the larger the switch voltage value is. The power supply control device 11 having this configuration can also achieve the same effects as in Embodiments 1 to 4.

Moreover, the transistor 41 may be an NPN bipolar transistor or an IGBT (Insulated Gate Bipolar Transistor), for example. A collector, an emitter, and a base of the NPN bipolar transistor correspond to the drain, the source, and the gate of the N-channel FET, respectively. A collector, an emitter, and a base of the IGBT correspond to the drain, the source, and the gate of the N-channel FET, respectively.

Furthermore, the third capacitor C3 may be indirectly connected between the two ends of the resistance R1. As one example, one end of the third capacitor C3 may be connected to one end of the first resistance R1 via the third resistance R3 and the conducting wire A4, and the other end of the third capacitor C3 may be connected to the other end of the first resistance R1 via the fourth resistance R4 and the conducting wire A5. As another example, one end of the third capacitor C3 may be connected to one end of the first resistance R1 via the conducting wire A4, and the other end of the third capacitor C3 may be connected to the other end of the first resistance R1 via the conducting wire A5. For the above two examples, a capacitor different from the third capacitor C3 may be directly connected between the two ends of the first resistance R1 to form a pi-type LC filter, according to Embodiments 2 and 4. This different capacitor functions as a fourth capacitor.

Moreover, the switch 20 according to Embodiments 1 to 4 is not limited to the N-channel FET and may be a P-channel FET, a bipolar transistor, or a relay contact, for example. Furthermore, a configuration to prevent an overcurrent is not limited to the form of software including the microcomputer 23, and may be a form of hardware including a comparator. In this case, the comparator compares the value of the voltage outputted from the current detection circuit 21 with a fixed voltage value, and outputs a high-level voltage or a low-level voltage depending on a result of the comparison. When the voltage outputted from the comparator indicates that the value of the voltage outputted from the current detection circuit 21 is larger than or equal to the fixed voltage value, the drive circuit 22 turns off the switch 20.

Embodiments 1 to 4 disclosed thus far only describe examples in all respects and are not intended to limit the scope of the present disclosure. It is intended that the scope of the present disclosure not be limited by the meanings described above, but be defined by the claims set forth below. Meanings equivalent to the description of the claims and all modifications are intended for inclusion within the scope of the following claims.

What is claimed is:

1. A power supply control device for controlling power supply via a switch by turning the switch on and off, the power supply control device comprising:
a resistance disposed on a path of a current flowing via the switch;
a differential amplifier outputting a voltage corresponding to a value of a voltage between two ends of the resistance;
a first capacitor connected between a point midway on a path of power supply to the differential amplifier and an upstream end of the resistance; and
a second capacitor connected between a point midway on the path of power supply and a downstream end of the resistance.

2. The power supply control device according to claim 1, further comprising:
a variable resistor having a first end connected to the upstream end of the resistance, and fluctuating in a resistance value between the first end and a second end depending on a value of the voltage outputted from the differential amplifier; and
a second resistance having one end connected to the second end of the variable resistor,
wherein a voltage is outputted from a connection node between the variable resistor and the second resistance.

3. The power supply control device according to claim 2,
wherein the variable resistor is a transistor,
the resistance value between the first end and the second end depends on a value of a voltage inputted to a control end of the variable resistor, and
the differential amplifier outputs a voltage to the control end.

4. The power supply control device according to claim 1,
wherein an end of the first capacitor on the supply-path side is connected to an end of the second capacitor on the supply-path side.

5. The power supply control device according to claim 4, further comprising:
a third resistance; and
a fourth resistance,
wherein the first capacitor is connected to the upstream end of the resistance via the third resistance, and
the second capacitor is connected to the downstream end of the resistance via the fourth resistance.

6. The power supply control device according to claim 1, wherein the first capacitor is connected at the point midway on the path of power supply via the second capacitor.

7. The power supply control device according to claim 1, wherein the second capacitor is connected at the point midway on the path of power supply via the first capacitor.

8. The power supply control device according to claim 6, further comprising:
a first inductor;
a second inductor; and
a third capacitor connected between the two ends of the resistance,
wherein the first capacitor is connected to the upstream end of the resistance via the first inductor, and
the second capacitor is connected to the downstream end of the resistance via the second inductor.

9. The power supply control device according to claim 1, further comprising:
a fourth capacitor connected between the two ends of the resistance.
